(19) United States
(12) Patent Application Publication
(10) Pub. No.: US 2026/0206307 A1
(43) Pub. Date: Jul. 16, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Chun Yi CHOU, Hsinchu (TW); Guan-Lin CHEN, Hsinchu (TW); Kuo-Cheng CHIANG, Hsinchu (TW); Chih-Hao WANG, Hsinchu (TW)

(21) Appl. No.: 19/200,760

(22) Filed: May 7, 2025

Related U.S. Application Data
(60) Provisional application No. 63/745,367, filed on Jan. 15, 2025.

(51) Int. Cl. H10D 84/85; H10D 84/01

(52) U.S. Cl. CPC H10D 84/851; H10D 84/0167; H10D 84/0188

(57) ABSTRACT

Embodiments of the present disclosure provide semiconductor device structures and methods of forming the same. The structure includes a source/drain region, a contact etch stop layer disposed over the source/drain region, a first interlayer dielectric (ILD) layer disposed over the contact etch stop layer, an etch stop layer disposed over the contact etch stop layer and the first ILD layer, a second ILD layer disposed over the etch stop layer, a substrate portion disposed below the source/drain region, and an isolation region disposed adjacent the substrate portion. The isolation region includes a first dielectric layer including a first dielectric material and a second dielectric layer disposed on the first dielectric layer. The second dielectric layer includes a second dielectric material different from the first dielectric material. The isolation region further includes a hard mask structure disposed on the first and second dielectric layers.

### CROSS-REFERENCE TO RELATED APPLICATIONS

This application claims priority to US Provisional Application Serial No. 63/745,367 filed January 15, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 are perspective views of various stages of manufacturing a semiconductor device structure, in accordance with some embodiments.

FIGS. 3, 4, 5, 6, 7, .89, 10 and 11, are cross-sectional side views of one of various stages of manufacturing the semiconductor device structure, in accordance with some embodiments.

FIG. 12 is a perspective view of one of various stages of manufacturing the semiconductor device structure, in accordance with some embodiments.

FIGS. 13, 14 and 15, are cross-sectional side views of various stages of manufacturing the semiconductor device structure taken along line A-A of FIG. 12, in accordance with some embodiments.

FIGS. 16 and 17 are cross-sectional side views of various stages of manufacturing the semiconductor device structure taken along line B-B of FIG. 12, in accordance with some embodiments.

FIGS. 18 and 19 are cross-sectional side views of various stages of manufacturing the semiconductor device structure taken along line C-C of FIG. 12, in accordance with some embodiments.

FIG. 20 is a cross-sectional side view of one of various stages of manufacturing the semiconductor device structure taken along line A-A of FIG. 12, in accordance with some embodiments.

FIGS. 21A and 21B are cross-sectional side views of one of various stages of manufacturing the semiconductor device structure taken along lines B-B, C-C of FIG. 12, respectively, in accordance with alternative embodiments.

FIGS. 22A and 22B are cross-sectional side views of one of various stages of manufacturing the semiconductor device structure taken along lines B-B, C-C of FIG. 12, respectively, in accordance with alternative embodiments.

FIGS. 23A and 23B are cross-sectional side views of one of various stages of manufacturing the semiconductor device structure taken along lines B-B, C-C of FIG. 12, respectively, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as "beneath," "below," "lower," "above," "over," "on," "top," "upper" and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

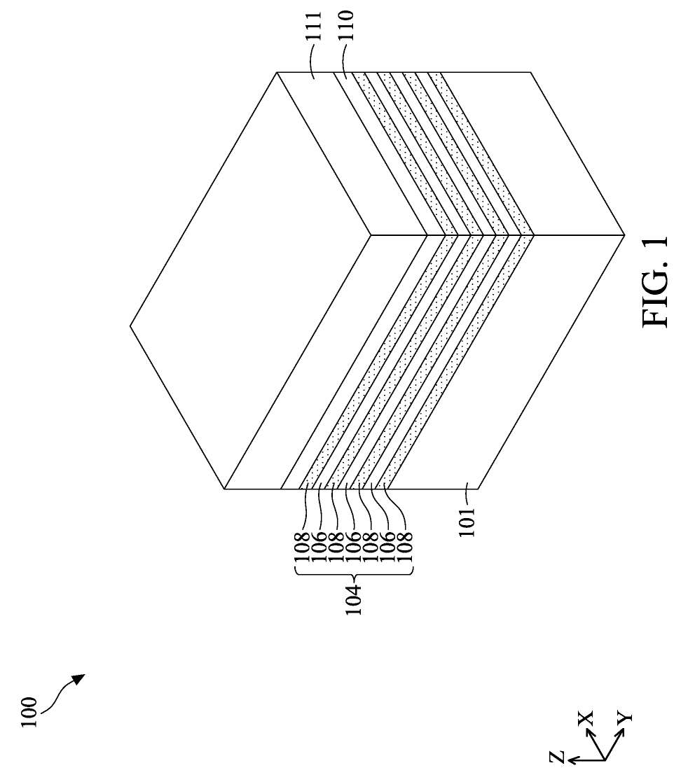

FIGS. 1 - 20 show exemplary processes for manufacturing a semiconductor device structure 100 according to embodiments of the present disclosure. It is understood that additional operations can be provided before, during, and after processes shown by FIGS. 1 - 20, and some of the operations described below can be replaced or eliminated, for additional embodiments of the method. The order of the operations/processes is not limiting and may be interchangeable.

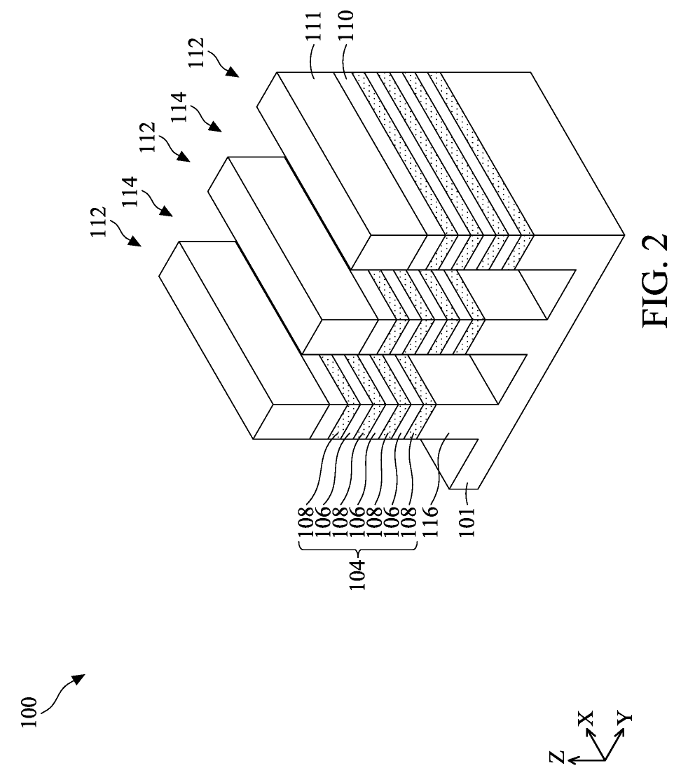

FIGS. 1 and 2 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InA1As), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, a nitride layer 110 is formed on the topmost first semiconductor layer 106, and an oxide layer 111 is formed on the nitride layer 110. The nitride layer 110 may be silicon nitride and may have different etch selectivity compared to the oxide layer 111. The oxide layer 111 may include any suitable nitride material, such as silicon oxide. In some embodiments, the nitride layer 110 and the oxide layer 111 may be a mask structure. The nitride layer 110 may be a protection layer to protect the stack of semiconductor layers 104 located therebelow.

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer, such as the nitride layer 110 and the oxide layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

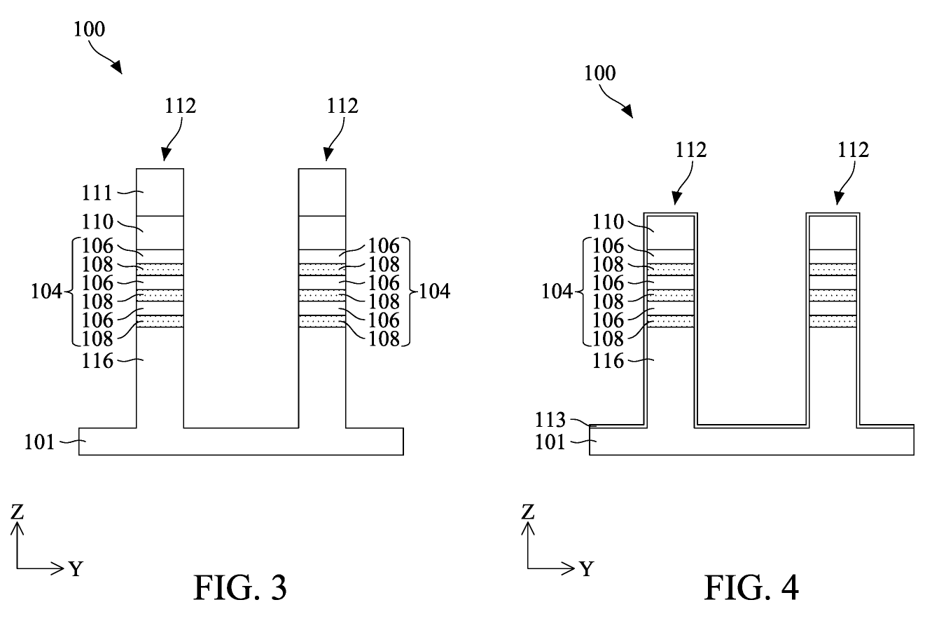

FIGS. 3, 4, 5, 6, 7, 8, 9, 10, and 11 are cross-sectional side views of one of various stages of manufacturing the semiconductor device structure 100, in accordance with some embodiments. FIG. 3 is a cross-sectional side view of the semiconductor device structure 100 shown in FIG. 2. Next, as shown in FIG. 4, the oxide layer 111 is removed, and an optional liner 113 is formed on the fin structures 112 and the substrate 101. The oxide layer 111 may be removed by any suitable process, such as a dry etch process, a wet etch process, or a combination thereof. The etch process to remove the oxide layer 111 may be a selective etch process that does not substantially affect the nitride layer 110 and the stack of semiconductor layers 104. The liner 113 may include a semiconductor material, such as silicon, for example amorphous silicon. The liner 113 may be used to protect the stack of semiconductor layers 104 from being oxidized. In some embodiments, the liner 113 is a conformal layer and is formed by a conformal process, such as atomic layer deposition (ALD). In some embodiments, the liner 113 is optional and not present.

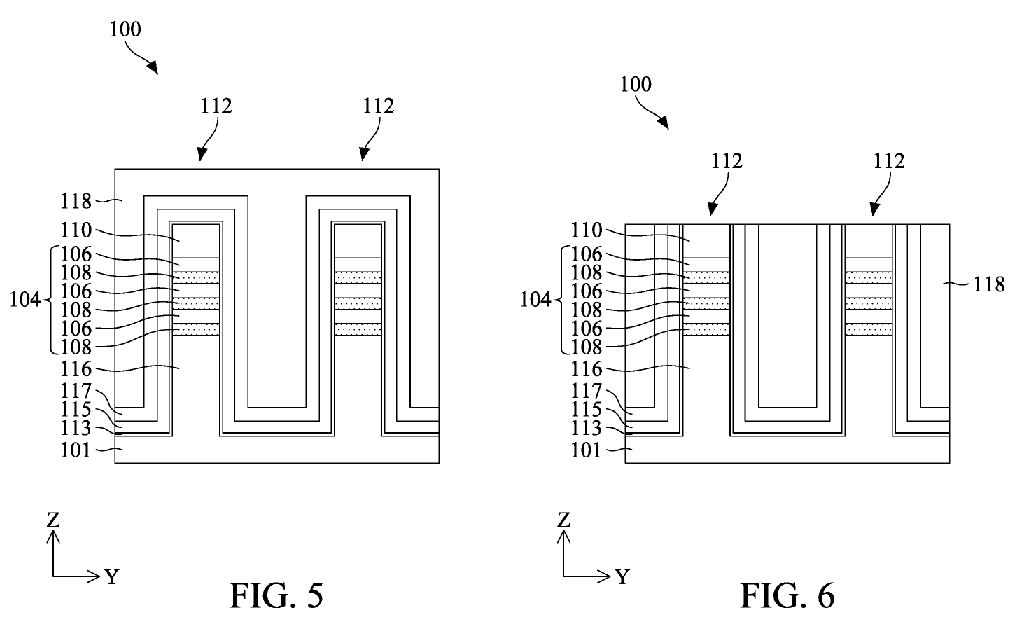

In FIG. 5, a first dielectric layer 115 is deposited on the liner 113, a second dielectric layer 117 is deposited on the first dielectric layer 115, and a third dielectric layer 118 is deposited on the second dielectric layer 117. In the embodiment that the liner 113 is not present, the first dielectric layer 115 is deposited around the fin structures 112. In some embodiments, the first dielectric layer 115 is an oxide layer, the second dielectric layer 117 is a nitrogen-containing or carbon-containing layer, and the third dielectric layer 118 is an oxide layer. In some embodiments, the first dielectric layer 115 includes SiOx and has a thickness ranging from about 0.5 nm to about 5 nm. The first dielectric layer 115 may be deposited by any suitable process, such as chemical vapor deposition (CVD), plasma enhanced chemical vapor deposition (PECVD), or ALD. In some embodiments, the first dielectric layer 115 is a conformal layer formed by ALD.

The second dielectric layer 117 includes SiN, SiCN, SiOC, SiOCN, SiC, or other suitable nitrogen-containing or carbon-containing material. In some embodiments, the material of the second dielectric layer 117 is different from the material of the first dielectric layer 115. For example, the k value of the second dielectric layer 117 may be greater than the k value of the first dielectric layer 115. The second dielectric layer 117 may function as a protection layer during subsequent processes. In some embodiments, the second dielectric layer 117 ensures that the side surfaces of the substrate portions 116 are not exposed by protecting the first dielectric layer 115 during subsequent processes. However, if the second dielectric layer 117 is directly deposited on a semiconductor material, such as the substrate portion 116 or the liner 113, fixed charge may generate at the interface between the substrate portion 116 or the liner 113 and the second dielectric layer 117. Fixed charge formed at the interface between the substrate portion 116 or the liner 113 and the second dielectric layer 117 can lead to current leakage. Thus, in some embodiments, the first dielectric layer 115 is deposited between the substrate portion 116 and the second dielectric layer 117 to prevent the generation of the fixed charge, as shown in FIG. 5. In some embodiments, if the thickness of the first dielectric layer 115 is less than about 0.5 nm, fixed charge may still form between the second dielectric layer 117 and the substrate portion 116. On the other hand, if the thickness of the first dielectric layer 115 is greater than about 5 nm, the first dielectric layer 115 may be etched to expose the side surfaces of the substrate portion 116 during subsequent processes. In some embodiments, the thickness of the second dielectric layer 117 ranges from about 0.5 nm to about 10 nm. If the thickness of the second dielectric layer 117 is less than about 0.5 nm, the second dielectric layer 117 is not thick enough to protect the first dielectric layer 115. On the other hand, if the thickness of the second dielectric layer 117 is greater than about 10 nm, capacitance would increase due to high k value of the second dielectric layer 117. The second dielectric layer 117 may be formed by any suitable process, such as CVD, PECVD, or ALD. In some embodiments, the second dielectric layer 117 is a conformal layer formed by ALD, as shown in FIG. 5.

As shown in FIG. 5, the third dielectric layer 118 is deposited on the second dielectric layer 117 and fills the trenches 114 between neighboring fin structures 112. The third dielectric layer 118 may be made of silicon oxide, fluorine-doped silicate glass (FSG), a low-k dielectric material, or any suitable dielectric material. In some embodiments, the third dielectric layer 118 include the same material as the first dielectric layer 115. The third dielectric layer 118 may be formed by any suitable method, such as low-pressure chemical vapor deposition (LPCVD), PECVD, or flowable CVD (FCVD). The third dielectric layer 118 has a lower k value compared to the second dielectric layer 117. Thus, if the third dielectric layer 118 is made of the same material as the second dielectric layer 117, the capacitance would be too high.

As shown in FIG. 6, a planarization operation, such as a chemical mechanical polishing (CMP) method and/or an etch-back method, is performed such that the top of the fin structures 112 is exposed. In some embodiments, the planarization process removes the portions of the third dielectric layer 118, the second dielectric layer 117, the first dielectric layer 115, and the liner 113 located over the nitride layer 110. In some embodiments, the nitride layer 110 functions as a CMP stop layer during the CMP process. The nitride layer 110 protects the topmost first semiconductor layers 106 during the planarization process.

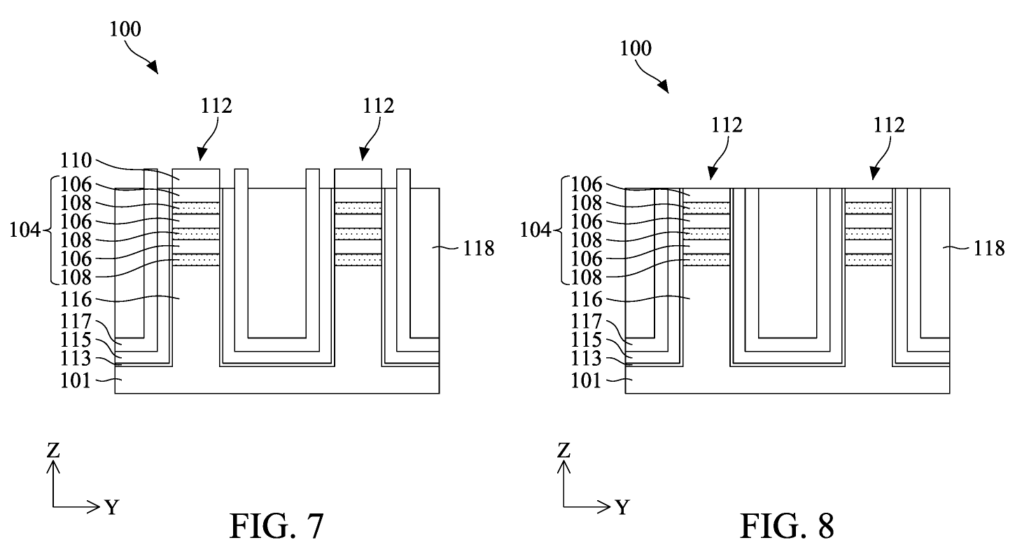

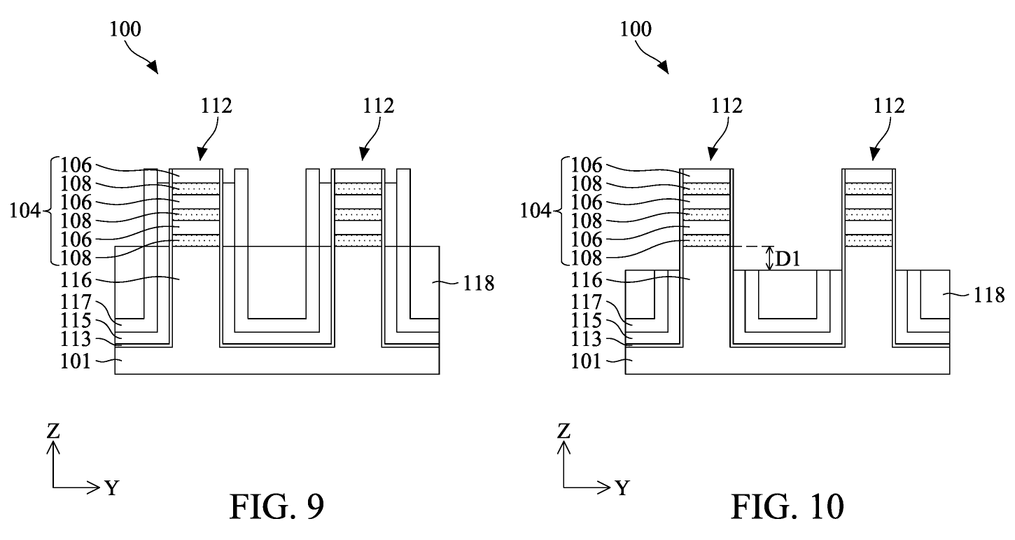

As shown in FIG. 7, the first dielectric layer 115 and the third dielectric layer 118 are recessed, and side surfaces of the nitride layer 110 are exposed. In some embodiments, the recessing of the first and third dielectric layers 115, 118 is performed by a selective etching process, such as a selective dry etching process. The selective dry etching process recesses the first and third dielectric layers 115, 118 until the side surfaces of the nitride layer 110 are exposed. Portions of the second dielectric layer 117 may be also exposed as the result of the selective dry etching process. The selective etching process does not substantially affect the nitride layer 110 and the second dielectric layer 117. Next, as shown in FIG. 8, the exposed portions of the second dielectric layer 117 and the nitride layer 110 are removed. In some embodiments, a wet etching process is performed to remove the exposed portions of the second dielectric layer 117 and the nitride layer 110. For example, a H₃PO₄ solution is used in the wet etching process to remove the exposed portions of the second dielectric layer 117 and the nitride layer 110. The wet etching process may be a selective process that does not substantially affect the materials of the first and third dielectric layers 115, 118 and the first semiconductor layer 106.

As shown in FIG. 9, the first and third dielectric layers 115, 118 are further recessed. In some embodiments, a selective dry etching process may be performed to recess the first and third dielectric layers 115, 118. The selective dry etching process may be the same selective dry etching process described in FIG. 7, except that the selective dry etching process is performed for a longer period of time compared to the selective dry etching process described in FIG. 7. In some embodiments, the heights of the first and third dielectric layers 115, 118 are different due to the loading effect. The height of the first dielectric layer 115 may be substantially greater than the height of the third dielectric layer 118, as shown in FIG. 9. Next, as shown in FIG. 10, portions of the first and second dielectric layers 115, 117 disposed along the sidewalls of the fin structures 112 are removed. In some embodiments, a first wet etching process may be performed to remove the portions of the second dielectric layer 117, and the wet etching process may utilize a H₃PO₄ solution to remove the portions of the second dielectric layer 117. Then, a selective dry etching process is performed to remove the portions of the first dielectric layer 115. The selective dry etching process may also recess the third dielectric layer 118, as shown in FIG. 10. In some embodiments, the resulting first, second, and third dielectric layers 115, 117, 118 have top surfaces that are substantially coplanar. In some embodiments, a vertical distance D1 is between the coplanar top surfaces of the first, second, and third dielectric layers 115, 117, 118 and a bottom surface of the bottommost second semiconductor layer 108, as shown in FIG. 10. The distance D1 may range from about 8 nm to about 20 nm.

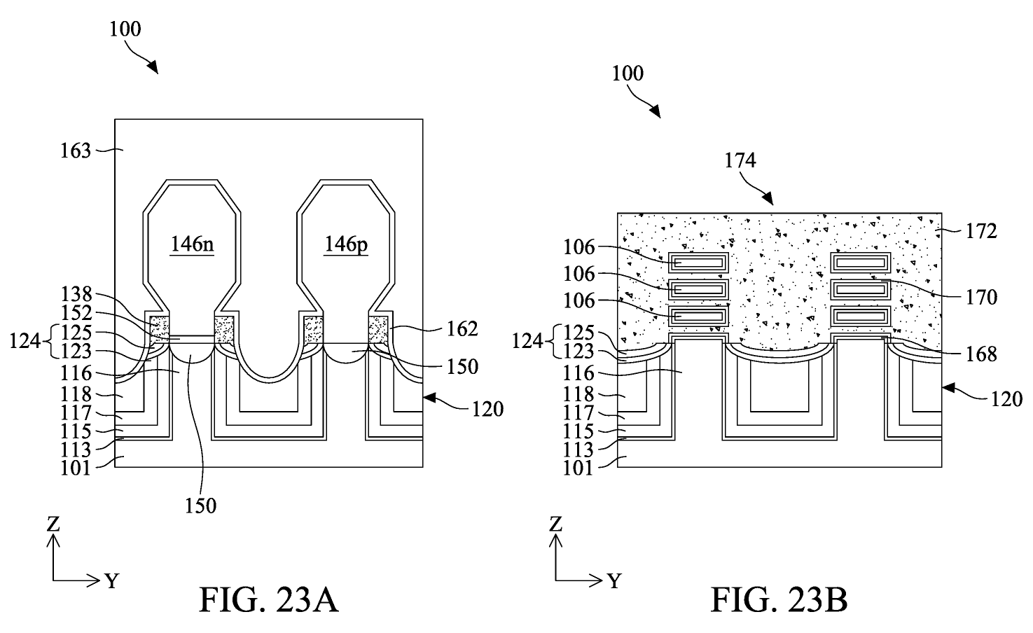

In some embodiments, as shown in FIG. 10, the top surfaces of the first, second, third dielectric layers 115, 117, 118 are substantially flat. In some embodiments, the top surfaces of the first, second, third dielectric layers 115, 117, 118 are curved (FIG. 23B), as a result of the multiple etching processes described in FIGS. 9 and 10.

As shown in FIG. 11, a hard mask structure 124 is formed on the first, second, and third dielectric layers 115, 117, 118. In some embodiments, the hard mask structure 124 has a height that is the same as the distance D1. The hard mask structure 124 may include an oxide layer 123 and a protection layer 125. In some embodiments, the oxide layer 123 includes the same material as the first dielectric layer 115, and the protection layer 125 includes the same material as the second dielectric layer 117. Similar to the first and second dielectric layers 115, 117, the oxide layer 123 is disposed between the protection layer 125 and the substrate portion 116 or the liner 113 to prevent generation of fixed charge. In some embodiments, the oxide layer 123 has a thickness ranging from about 0.5 nm to about 3 nm. In some embodiments, if the thickness of the oxide layer 123 is less than about 0.5 nm, fixed charge may still form at the interface between the protection layer 125 and the oxide layer 123. On the other hand, if the thickness of the oxide layer 123 is greater than about 3 nm, the oxide layer 123 may be etched to expose the side surfaces of the substrate portion 116 during subsequent processes. In some embodiments, the thickness of the protection layer 125 ranges from about 0.5 nm to about 20 nm. If the thickness of the protection layer 125 is less than about 0.5 nm, the protection layer 125 is not thick enough to protect the oxide layer 123. On the other hand, if the thickness of the protection layer 125 is greater than about 20 nm, capacitance would increase due to high k value of the protection layer 125.

In some embodiments, the first, second, and third dielectric layers 115, 117, 118 and the hard mask structure 124 disposed between adjacent fin structures 112 form an isolation regions 120. The isolation regions 120 may be the shallow trench isolation (STI). In some embodiments, as shown in FIG. 11, the top surface of the isolation region 120 (i.e., the top surfaces of the oxide layer 123 and the protection layer 125) may be located at a level at or below the bottom surface of the bottommost second semiconductor layer 108.

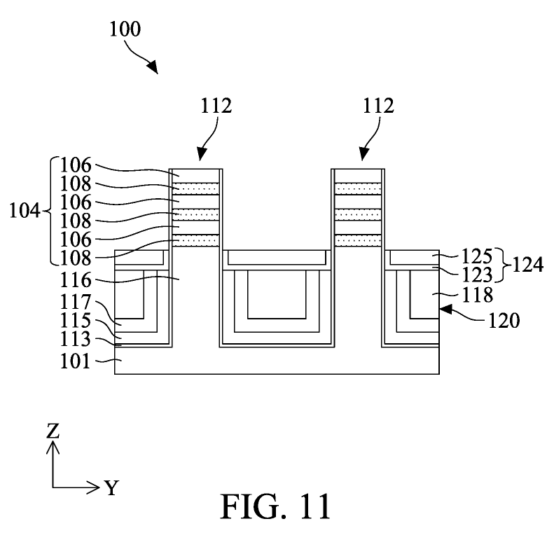

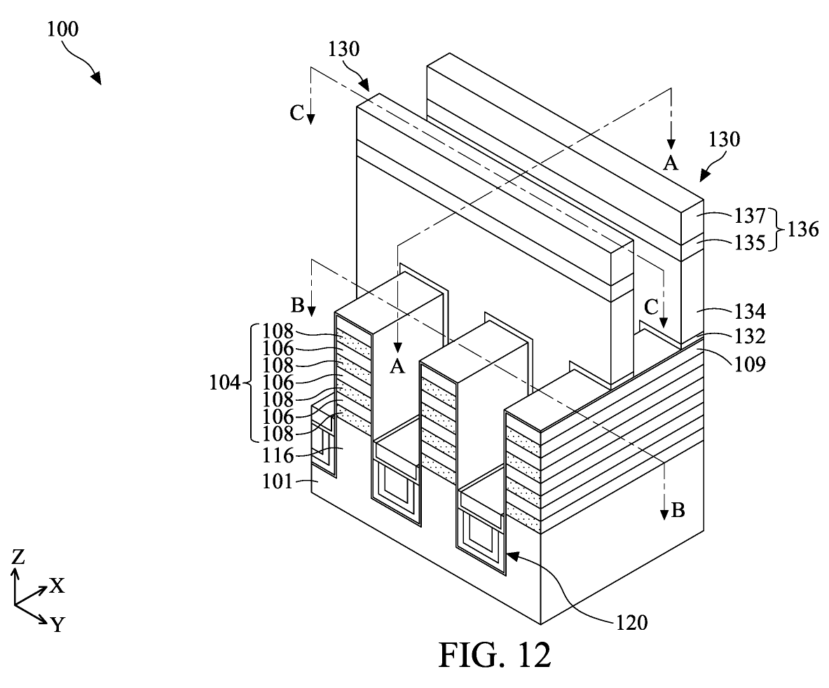

FIG. 12 is a perspective view of one of various stages of manufacturing the semiconductor device structure 100, in accordance with some embodiments. As shown in FIG. 12, one or more sacrificial gate structures 130 are formed over the semiconductor device structure 100. The sacrificial gate structures 130 are formed over first portions of the fin structures 112 and first portions of the isolation regions 120, while second portions of the fin structures 112 and second portions of the isolation regions 120 are exposed. Each sacrificial gate structure 130 may include a sacrificial gate dielectric layer 132, a sacrificial gate electrode layer 134, and a mask layer 136. In some embodiments, the mask layer 136 is a multi-layer structure. For example, the mask layer 136 includes an oxide layer 135 and a nitride layer 137 formed on the oxide layer 135. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. The sacrificial gate dielectric layer 132 may include one or more layers of dielectric material, such as a silicon oxide-based material. The sacrificial gate electrode layer 134 may include silicon, such as polycrystalline silicon or amorphous silicon. The portions of the fin structures 112 that are covered by the sacrificial gate electrode layer 134 of the sacrificial gate structure 130 serve as channel regions for the semiconductor device structure 100. In some embodiments, the liner 113 located on the second portions of the fin structures 112 may be removed during the patterning processes. The liner 113 formed on the first portions of the fin structures 112 and adjacent to the isolation regions 120 is omitted for clarity.

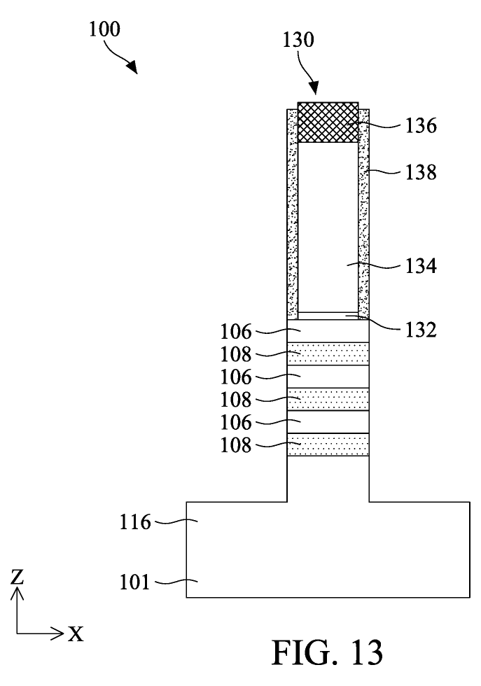

FIGS. 13, 14 and 15, are cross-sectional side views of various stages of manufacturing the semiconductor device structure 100 taken along line A-A of FIG. 12, in accordance with some embodiments. As shown in FIG. 13, spacers 138 are formed on the sidewalls of the sacrificial gate structures 130. The spacers 138 may be formed by depositing a dielectric layer on the exposed surfaces of the semiconductor device structure 100, followed by an anisotropic etching process to remove horizontal portions of the dielectric layer. The spacer 138 may be made of a dielectric material such as silicon oxide, silicon nitride, silicon carbide, silicon oxynitride, SiCN, silicon oxycarbide, SiCON, and/or combinations thereof. In some embodiments, the spacer 138 includes a multi-layer structure. The spacers 138 may be formed on the sidewalls of the sacrificial gate structures 130 and on the sidewalls of the exposed portions of the fin structures 112 (FIG. 12).

Next, as shown in FIG. 13, one or more etching processes are performed to recess the portions of the fin structures 112 not covered by the sacrificial gate structures 130 and the spacers 138. In some embodiments, the portions of the fin structures 112 not covered by the sacrificial gate structure 130 and the spacers 138 are recessed to a level above, at, or below the top surfaces of the isolation regions 120. The recess of the portions of the fin structures 112 can be done by an etch process, either isotropic or anisotropic etch process. The etch process may be a dry etch, such as a RIE, NBE, or the like, or a wet etch, such as using tetramethyalammonium hydroxide (TMAH), ammonium hydroxide (NH₄0H), or any suitable etchant. After the recess the portions of the fin structures 112, the substrate portions 116 may be exposed on opposite sides of the sacrificial gate structure 130, as shown in FIG. 13.

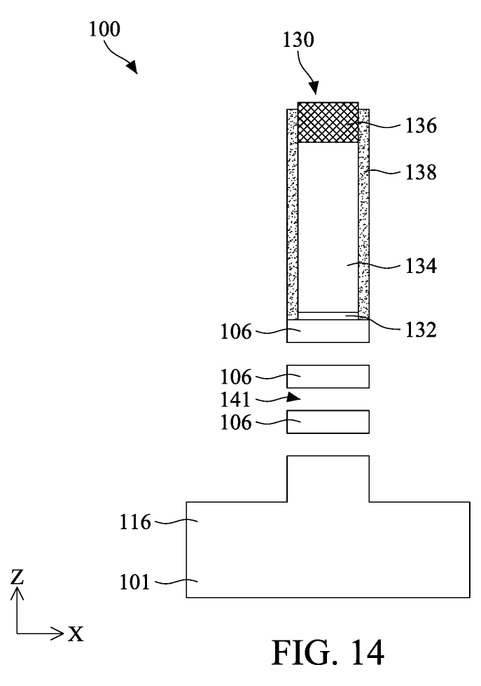

As shown in FIG. 14, the second semiconductor layers 108 are removed. In some embodiments, the second semiconductor layers 108 include Ge, and the subsequently formed source/drain (S/D) regions include phosphorus doped silicon for n-type FET. The Ge in the second semiconductor layers 108 and the phosphorus in the S/D regions can inter-diffuse, which may induce high interfacial state density (Dit) on the first semiconductor layers 106. As a result, n-type device mobility may be degraded. Thus, in some embodiments, the second semiconductor layers 108 are removed prior to the formation of the S/D regions. In some embodiments, the second semiconductor layers 108 are completely removed, and openings 141 are formed between vertically adjacent first semiconductor layers 106, as shown in FIG. 14. The second semiconductor layers 108 may be removed by a selective etching process, such as a selective dry etching process, a selective wet etching process, or a combination thereof. The selective etching process does not substantially affect the spacers 138 and the first semiconductor layers 106.

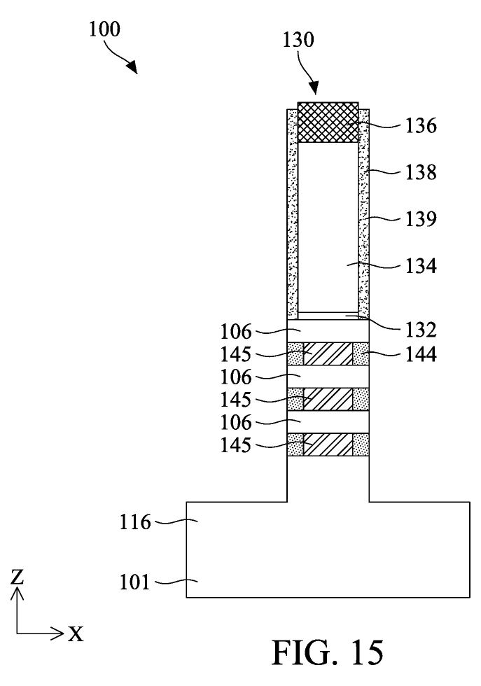

As shown in FIG. 15, a dielectric layer 145 is formed in the openings 141, and the dielectric layer 145 is capped by dielectric spacers 144 along the X direction. The dielectric layer 145 may be formed by first depositing a dielectric layer in the openings 141 and on the semiconductor device structure 100. The dielectric layer may be formed by any suitable process, such as CVD, PECVD, FCVD, or ALD. The dielectric layer may include any suitable dielectric material. In some embodiments, the dielectric layer includes an oxide, such as silicon oxide. In some embodiments, the dielectric layer 145 includes the same material as the third dielectric layer 118. Next, an anisotropic etching process is performed to remove the portions of the dielectric layer other than the portions of the dielectric layer formed in the openings 141. Next, edge portions of the dielectric layer are removed horizontally along the X direction to form the dielectric layer 145. The removal of the edge portions of the dielectric layer forms cavities. In some embodiments, the edge portions of the dielectric layer are removed by a selective wet etching process. After forming the dielectric layer 145, a dielectric layer is deposited in the cavities to form dielectric spacers 144, as shown in FIG. 15. The dielectric spacers 144 may be made of a dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. In some embodiments, the dielectric spacers 144 and the dielectric layer 145 include different materials having different etch selectivity.

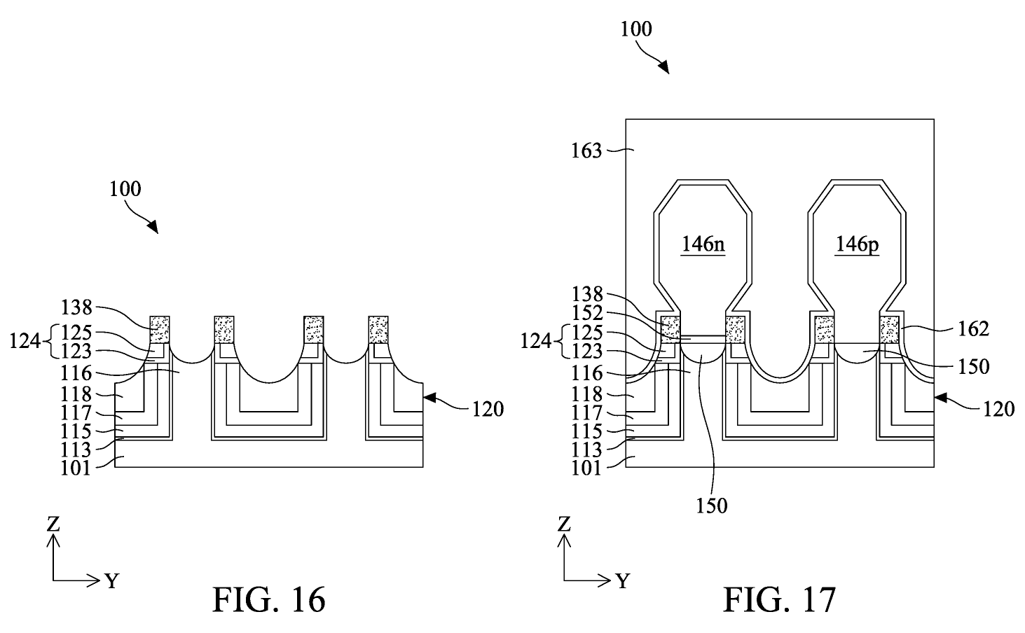

FIGS. 16 and 17 are cross-sectional side views of various stages of manufacturing the semiconductor device structure 100 taken along line B-B of FIG. 12, in accordance with some embodiments. As shown in FIG. 16, the processes to recess the portions of the fin structures 112 and to form the dielectric layers 145 and the dielectric spacers 144 also recess the isolation regions 120. For example, the one or more etching processes to recess the portions of the fin structures 112 not covered by the sacrificial gate structures 130 and the spacers 138 described in FIG. 13 may also recess the spacers 138 formed on the sidewalls of the exposed portions of the fin structures 112 and the hard mask structure 124. The recessed spacers 138 may be disposed on the hard mask structures 124, as shown in FIG. 16. In some embodiments, the etching process to form the dielectric layer 145 may further recess the hard mask structure 124 and the portion of the third dielectric layer 118 located under the hard mask structure 124. In some embodiments, without the second dielectric layer 117, the third dielectric layer 118 and the first dielectric layer 115 may be recessed to expose the substrate portion 116 or the liner 113. As a result, subsequently formed S/D regions 146n, 146p may merge. With the presence of the second dielectric layer 117, which is made of a material different from the materials of the first and third dielectric layers 115, 118, the various processes described above do not substantially affect the second dielectric layer 117. As a result, merging of adjacent S/D regions 146n, 146p is avoided. In some embodiments, the presence of the hard mask structure 124 also protects the second dielectric layer 117. Without the hard mask structure 124, the second dielectric layer 117 may be etched through.

In some embodiments, as shown in FIG. 16, the exposed surfaces of the protection layer 125, the oxide layer 123, the third dielectric layer 118, and the second dielectric layer 117 together may form a curved surface, such as a concave surface.

As shown in FIG. 17, an interposing layer is formed between the substrate portions 116 and the source/drain regions 146n, 146p. In some embodiments, the interposing layer is a semiconductor layer 150 formed on the exposed portion of the substrate portion 116, and S/D regions 146n, 146p are formed over the semiconductor layer 150. In some embodiments, the semiconductor layer 150 may include undoped silicon or undoped SiGe. The term undoped may include materials being unintentionally doped. For example, the interposing layer 150 may be undoped at the time of deposition, but may contain dopant diffused from other regions during subsequent processes. The S/D regions 146n may be S/D epitaxial features formed in an n-type device region, and the S/D regions 146p may S/D epitaxial features formed in a p-type device region. The S/D regions 146n, 146p may be formed at different times using masks. For example, a mask is formed on the substrate portions 116 in the p-type device region, and the S/D regions 146n are formed over the substrate portions 116 in the n-type device region. Then, the mask in the p-type device region is removed, and another mask is formed on the S/D regions 146n. The S/D regions 146p are then formed over the substrate portions 116 in the p-type region.

In some embodiments, the interposing layer may be a dielectric layer 152 formed between the substrate portions 116 and the S/D regions 146n, as shown in FIG. 17. The dielectric layer 152 may include any suitable dielectric material, such as SiN. In some embodiments, the interposing layer includes the semiconductor layer 150, the dielectric layer 152, or a combination thereof. The interposing layer may prevent current leakage. In some embodiments, the dielectric layer 152 is also formed between the semiconductor layer 150 and the S/D regions 146p. In some embodiments, the dielectric layer 152 is formed in one of the n-type device region and the p-type device region. In some embodiments, the dielectric layer 152 is formed in both n-type device region and p-type device region.

In some embodiments, the S/D regions 146n, 146p may grow both vertically and horizontally to form facets, which may correspond to crystalline planes of the material used for the first semiconductor layers 106 and the semiconductor layer 150. In this disclosure, a source region and a drain region are interchangeably used, and the structures thereof are substantially the same. Furthermore, source/drain region(s) may refer to a source or a drain, individually or collectively dependent upon the context. In some embodiments, the S/D regions 146n are n-type S/D epitaxial features and may be made of one or more layers of Si, SiP, SiC and SiCP for n-channel FETs. In some embodiments, the S/D regions 146p are p- type epitaxial features and may be made of one or more layers of Si, SiGe, Ge for p-channel FETs. For p-channel FETs, p-type dopants, such as boron (B), may also be included in the S/D regions 146p. The S/D regions 146n, 146p may be formed by an epitaxial growth method using CVD, ALD or MBE. In some embodiments, a thickness of the S/D region 146n or 146p along the Z direction is different from a width of the S/D region 146n or 146p along the Y direction. In some embodiments, the S/D region 146n or 146p includes two or more epitaxial layers having different dopant concentrations.

As shown in FIG. 17, after the formation of the S/D regions 146n, 146p, a contact etch stop layer (CESL) 162 is conformally formed on the exposed surfaces of the semiconductor device structure 100. The CESL 162 covers the sidewalls of the spacers 138 and is disposed on the S/D regions 146n, 146p. In some embodiments, the CESL 162 is in contact with or interfaces the spacer 138, the protection layer 125, the oxide layer 123, the third dielectric layer 118, and the second dielectric layer 117, as shown in FIG. 17. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 163 is formed on the CESL 162. The materials for the ILD layer 163 may include compounds including Si, O, C, and/or H, such as silicon oxide, SiCOH, or SiOC. Organic materials, such as polymers, may also be used for the ILD layer 163. The ILD layer 163 may be deposited by a PECVD process or other suitable deposition technique. In some embodiments, after formation of the ILD layer 163, the semiconductor device structure 100 may be subject to a thermal process to anneal the ILD layer 163.

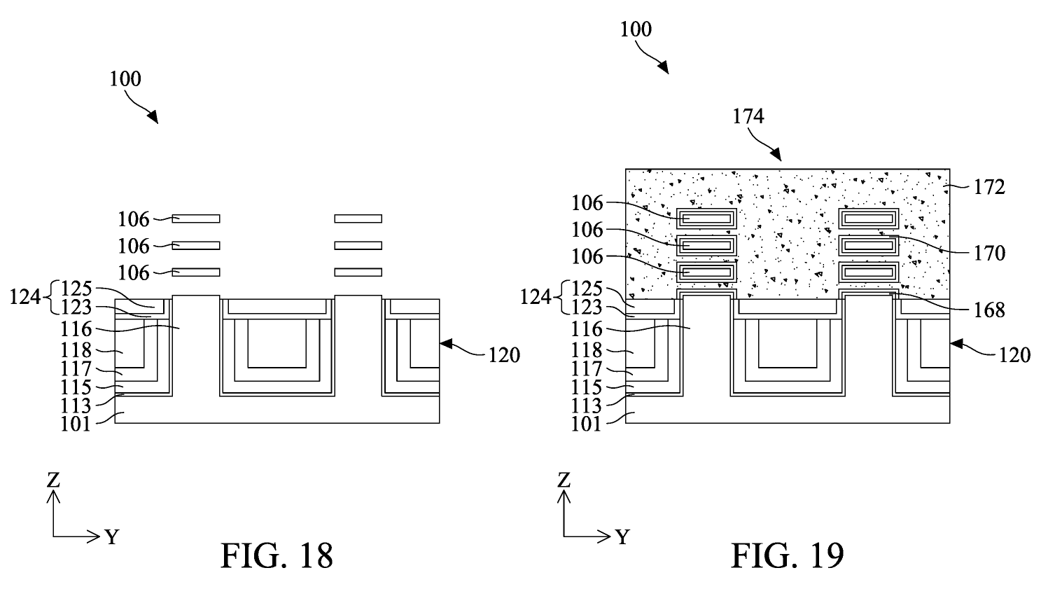

FIGS. 18 and 19 are cross-sectional side views of various stages of manufacturing the semiconductor device structure 100 taken along line C-C of FIG. 12, in accordance with some embodiments. After forming the ILD layer 163, a planarization process is performed to expose the sacrificial gate electrode layers 134, and the sacrificial gate structures 130 and the dielectric layers 145 are removed, as shown in FIG. 18. The planarization process may be any suitable process, such as a CMP process. The planarization process removes portions of the ILD layer 163 and the CESL 162 disposed on the sacrificial gate structures 130. The planarization process may also remove the mask layer 136. The sacrificial gate electrode layer 134 may be first removed by any suitable process, such as dry etching process, wet etching process, or a combination thereof, followed by the removal of the sacrificial gate dielectric layer 132, which may be performed by any suitable process, such as dry etching process, wet etching process, or a combination thereof. In some embodiments, a wet etchant such as a tetramethylammonium hydroxide (TMAH) solution can be used to selectively remove the sacrificial gate electrode layer 134 but not the spacers 138, the ILD layer 163, and the CESL 162. The dielectric layers 145 may be removed by any suitable process. In some embodiments, the dielectric layers 145 are removed by a selective etching process. The selective etching process removes the dielectric layers 145 between the first semiconductor layers 106 but does not remove the first semiconductor layers 106, the ILD layer 163, the CESL 162, the spacers 138, and the protection layer 125 of the hard mask structure 124, as shown in FIG. 18. The protection layer 125 of the hard mask structure 124 protects the third dielectric layer 118 from being recessed by the selective etching process. The portion of each first semiconductor layer 106 not covered by the dielectric spacers 144 may be exposed after the removal of the dielectric layers 145. Each first semiconductor layer 106 may be a nanostructure channel.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170, as shown in FIG. 19. The gate dielectric layer 170 and the gate electrode layer 172 may be collectively referred to as a gate structure 174. In some embodiments, an interfacial layer (IL) 168 is formed between the gate dielectric layer 170 and the exposed surfaces of the first semiconductor layers 106. The IL 168 may include an oxide, such as silicon oxide. In some embodiments, the gate dielectric layer 170 includes one or more layers of a dielectric material, such as silicon oxide, silicon nitride, or high-K dielectric material, other suitable dielectric material, and/or combinations thereof. Examples of high- K dielectric material include HfO2, HfSiO, HfSiON, HfTaO, HfTiO, HfZrO, zirconium oxide, aluminum oxide, titanium oxide, hafnium dioxide-alumina (HfO2-Al203) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate dielectric layer 170 and the gate electrode layer 172 may be also deposited over the ILD layer 163. The gate dielectric layer 170 and the gate electrode layer 172 formed over the ILD layer 163 are then removed by using, for example, CMP, until the top surface of the ILD layer 163 is exposed.

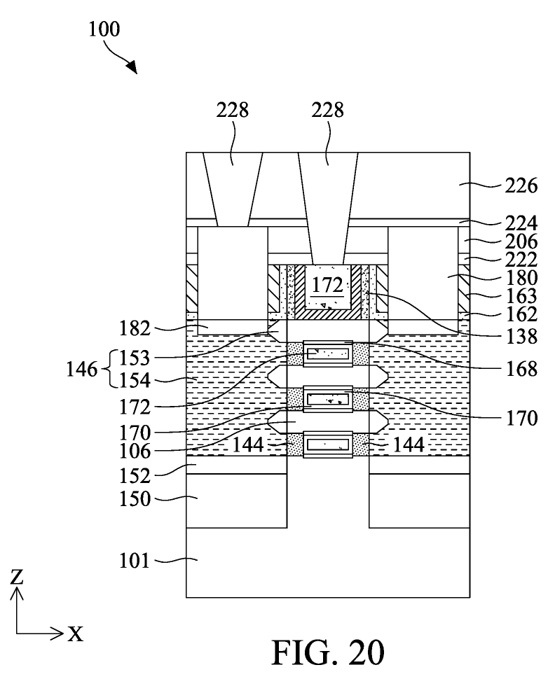

FIG. 20 is a cross-sectional side view of one of various stages of manufacturing the semiconductor device structure 100 taken along line A-A of FIG. 12, in accordance with some embodiments. As shown in FIG. 20, in some embodiments, the S/D region 146 (146n or 146p) includes two or more epitaxial layers, such as a first epitaxial layer 153 and a second epitaxial layer 154. The first and second epitaxial layers 153, 154 may include the same semiconductor material but with different dopant concentrations. In some embodiments, the first and second epitaxial layers 153, 154 includes different compositions.

As shown in FIG. 20, after the CMP process to expose the ILD layer 163, an etch stop layer 222 and another ILD layer 206 are formed on the ILD layer 163 and the gate structures 174. In some embodiments, the etch stop layer 222 includes the same material as the CESL 162. The ILD layer 206 may include the same material as the ILD layer 163. In some embodiments, the thickness of the ILD layer 163 is greater than a thickness of the ILD layer 206. Next, conductive contacts 180 are formed in the ILD layer 206 and the etch stop layer 222, and the silicide layers 182 are formed between the conductive contacts 180 and the S/D regions 146n. Next, another etch stop layer 224 and another ILD layer 226 are formed on the conductive contacts 180 and the ILD layer 206, as shown in FIG. 20. In some embodiments, the etch stop layer 224 includes the same material as the etch stop layer 222. Next, as shown in FIG. 20, conductive features 228 are formed in the ILD layer 226, the etch stop layer 224, the ILD layer 206, and the etch stop layer 222. The conductive features 228 are electrically connected to the gate electrode layer 172 and the conductive contact 180.

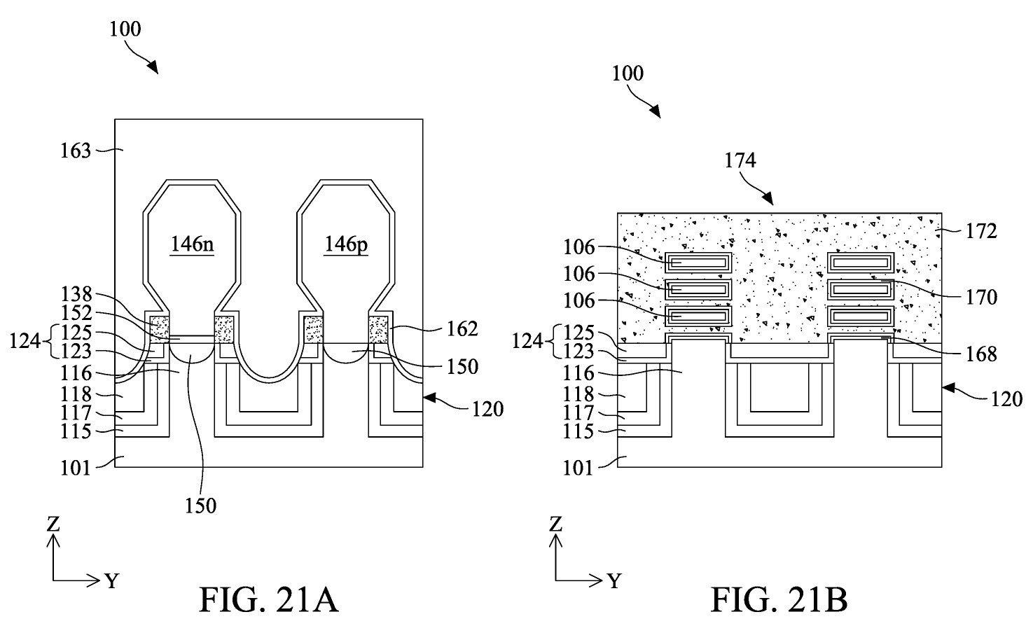

FIGS. 21A and 21B are cross-sectional side views of one of various stages of manufacturing the semiconductor device structure 100 taken along lines B-B, C-C of FIG. 12, respectively, in accordance with alternative embodiments. In some embodiments, the liner 113 is not present, and the first dielectric layer 115 is deposited on and interfacing the substrate portion 116, as shown in FIGS. 21A and 21B.

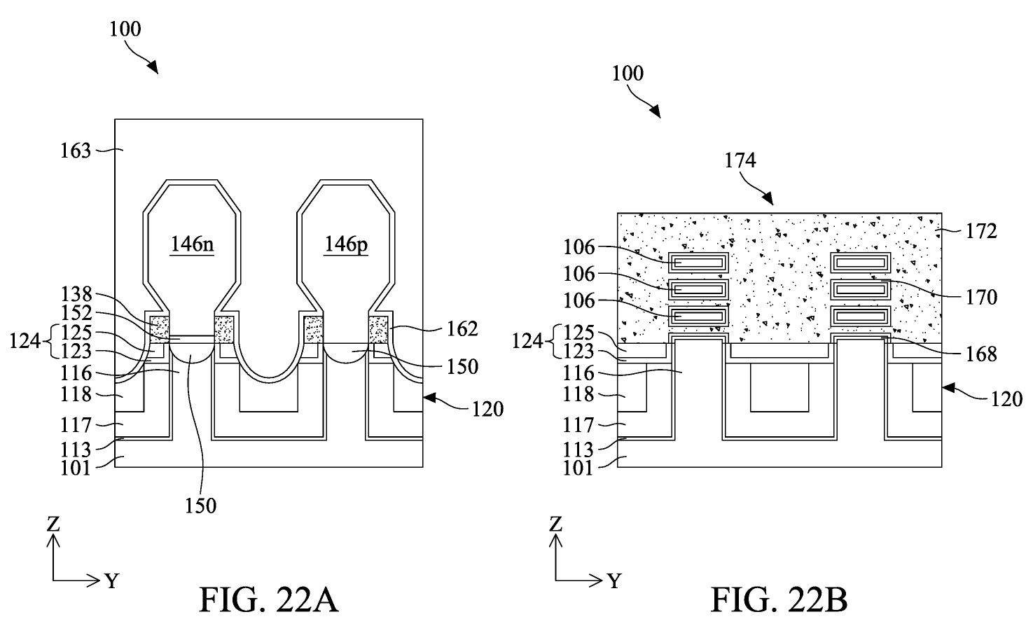

FIGS. 22A and 22B are cross-sectional side views of one of various stages of manufacturing the semiconductor device structure 100 taken along lines B-B, C-C of FIG. 12, respectively, in accordance with alternative embodiments. In some embodiments, the first dielectric layer 115 is not present, and the second dielectric layer 117 is deposited on and interfacing the substrate portion 116 or the liner 113, as shown in FIGS. 22A and 22B.

FIGS. 23A and 23B are cross-sectional side views of one of various stages of manufacturing the semiconductor device structure 100 taken along lines B-B, C-C of FIG. 12, respectively, in accordance with alternative embodiments. In some embodiments, the top surfaces of the first, second, third dielectric layers 115, 117, 118 together form a curved surface, as a result of the multiple etching processes described in FIGS. 9 and 10. In some embodiments, the bottom surface of the hard mask structure 124 is also curved. For example, the top surfaces of the first, second, third dielectric layers 115, 117, 118 together may form a concave surface, and the bottom surface of the hard mask structure 124 may form a convex surface. In some embodiments, the oxide layer 123 and the protection layer 125 are both conformal layers, and the top surface of the hard mask structure 124 may be curved, such as concave.

In some embodiments, the curvature of the concave surface made of the combined surfaces of the protection layer 125, the oxide layer 123, the third dielectric layer 118, and the second dielectric layer 117 shown in FIG. 23A is different from the curvature of the concave surface made of the combined top surfaces of the first, second, and third dielectric layers 115, 117, 118 shown in FIG. 23B.

Embodiments of the present disclosure provide a semiconductor device structure 100 including an isolation region 120 including at least a dielectric layer 117, a dielectric layer 118, and a hard mask structure 124 disposed on the dielectric layers 117, 118. Some embodiments may achieve advantages. For example, the dielectric layer 117 and a protection layer 125 of the hard mask structure 124 prevent a substrate portion 116 from being exposed. As a result, merging of the S/D regions 146n, 146p may be avoided.

An embodiment is a semiconductor device structure. The structure includes a source/drain region including a first epitaxial layer and a second epitaxial layer, and the first epitaxial layer and the second epitaxial layer are doped with a dopant. A concentration of the dopant in the first epitaxial layer is different from a concentration of the dopant in the second epitaxial layer, and a thickness of the source/drain region is different from a width of the source/drain region in a cross-sectional view. The structure further includes a contact etch stop layer disposed over the source/drain region, a first interlayer dielectric (ILD) layer disposed over the contact etch stop layer, an etch stop layer disposed over a top surface of the contact etch stop layer and a top surface of the first ILD layer, and a second ILD layer disposed over the etch stop layer. A thickness of the first ILD layer is greater than a thickness of the second ILD layer. The structure further includes a substrate portion disposed below the source/drain region and an isolation region disposed adjacent the substrate portion. The isolation region includes a first dielectric layer including a first dielectric material and a second dielectric layer disposed on the first dielectric layer. The second dielectric layer includes a second dielectric material different from the first dielectric material. The isolation region further includes a hard mask structure disposed on the first and second dielectric layers.

Another embodiment is a semiconductor device structure. The structure includes a first source/drain region including a first epitaxial layer and a second epitaxial layer, and the first epitaxial layer and the second epitaxial layer are doped with a dopant. A concentration of the dopant in the first epitaxial layer is different from a concentration of the dopant in the second epitaxial layer, and a thickness of the first source/drain region is different from a width of the first source/drain region in a cross-sectional view. The structure further includes a second source/drain region disposed adjacent the first source/drain region, a gate electrode layer disposed adjacent the first and second source/drain regions, a contact etch stop layer disposed over the first and second source/drain regions, a first interlayer dielectric (ILD) layer disposed over the contact etch stop layer, an etch stop layer disposed over a top surface of the contact etch stop layer and a top surface of the first ILD layer, and a second ILD layer disposed over the etch stop layer. A thickness of the first ILD layer is greater than a thickness of the second ILD layer. The structure further includes a first substrate portion disposed below the first source/drain region, a second substrate portion disposed below the second source/drain region, and an isolation region disposed between the first and second substrate portions. The isolation region includes a first dielectric layer and a hard mask structure disposed over the first dielectric layer, and the hard mask structure includes a first portion and a second portion. The contact etch stop layer extends through the first portion of the hard mask structure, and the gate electrode layer is disposed over the second portion of the hard mask structure.

A further embodiment is a method. The method includes forming a fin structure over a substrate, and the fin structure includes a substrate portion and a first protection layer over the substrate portion. The method further includes forming an isolation region adjacent the substrate portion. The method for forming the isolation region includes depositing a first dielectric layer around the fin structure, depositing a second dielectric layer on the first dielectric layer, depositing a third dielectric layer on the second dielectric layer, recessing the first dielectric layer to expose side surfaces of the first protection layer, removing the first protection layer, recessing the first and third dielectric layers, and recessing the first and second dielectric layers. The method further includes forming a source/drain region over the substrate portion. The source/drain region includes a first epitaxial layer and a second epitaxial layer, the first epitaxial layer and the second epitaxial layer are doped with a dopant, a concentration of the dopant in the first epitaxial layer is different from a concentration of the dopant in the second epitaxial layer, and a thickness of the source/drain region is different from a width of the source/drain region in a cross-sectional view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain region comprising a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the source/drain region is different from a width of the source/drain region in a cross-sectional view;
a contact etch stop layer disposed over the source/drain region;
a first interlayer dielectric (ILD) layer disposed over the contact etch stop layer;
an etch stop layer disposed over a top surface of the contact etch stop layer and a top surface of the first ILD layer;
a second ILD layer disposed over the etch stop layer, wherein a thickness of the first ILD layer is greater than a thickness of the second ILD layer;
a substrate portion disposed below the source/drain region; and
an isolation region disposed adjacent the substrate portion, wherein the isolation region comprises:
a first dielectric layer comprising a first dielectric material;
a second dielectric layer disposed on the first dielectric layer, wherein the second dielectric layer comprises a second dielectric material different from the first dielectric material; and
a hard mask structure disposed on the first and second dielectric layers.

2. The semiconductor device structure of claim 1, wherein the hard mask structure comprises an oxide layer and a protection layer disposed on the oxide layer.

3. The semiconductor device structure of claim 2, wherein the protection layer comprises the second dielectric material.

4. The semiconductor device structure of claim 3, wherein the first dielectric material comprises silicon oxide, and the second dielectric material comprises SiN, SiCN, SiOC, SiOCN, or SiC.

5. The semiconductor device structure of claim 1, further comprising a spacer disposed on the hard mask structure, wherein the spacer is adjacent the source/drain region.

6. The semiconductor device structure of claim 5, wherein the contact etch stop layer interfaces the spacer, the hard mask structure, the first dielectric layer, and the second dielectric layer.

7. The semiconductor device structure of claim 1, further comprising a semiconductor layer disposed between the substrate portion and the source/drain region, wherein the semiconductor layer is adjacent the hard mask structure.

8. The semiconductor device structure of claim 7, further comprising a third dielectric layer disposed between the semiconductor layer and the source/drain region.

9. A semiconductor device structure, comprising:a first source/drain region comprising a first epitaxial layer and a second epitaxial layer, wherein the first epitaxiallayer and the second epitaxial layer are doped with a dopant, a concentration of the dopant in the first epitaxial layer is different from a concentration of the dopant in the second epitaxial layer, and a thickness of the first source/drain region is different from a width of the first source/drain region in a cross-sectional view;a second source/drain region disposed adjacent the first source/drain region;a gate electrode layer disposed adjacent the first and second source/drain regions;a contact etch stop layer disposed over the first and second source/drain regions;a first interlayer dielectric (ILD) layer disposed over the contact etch stop layer;an etch stop layer disposed over a top surface of the contact etch stop layer and a top surface of the first ILD layer;a second ILD layer disposed over the etch stop layer, wherein a thickness of the first ILD layer is greater than a thickness of the second ILD layer;a first substrate portion disposed below the first source/drain region;a second substrate portion disposed below the second source/drain region; andan isolation region disposed between the first and second substrate portions, wherein the isolation region comprises a first dielectric layer and a hard mask structure disposed over the first dielectric layer, the hard mask structure comprises a first portion and a second portion,
wherein the contact etch stop layer extends through the first portion of the hard maskstructure, and the gate electrode layer is disposed over the second portion of thehard mask structure.

10. The semiconductor device structure of claim 9, wherein the second portion of the hard mask structure has a flat top surface.

11. The semiconductor device structure of claim 9, wherein the second portion of the hard mask structure has a curved top surface.

12. The semiconductor device structure of claim 9, wherein the hard mask structure comprises an oxide layer and a protection layer disposed on the oxide layer.

13. The semiconductor device structure of claim 12, wherein the first dielectric layer and the protection layer comprises a same material.

14. The semiconductor device structure of claim 9, wherein the isolation region further comprises a second dielectric layer disposed on the first dielectric layer, wherein the hard mask layer is disposed on the second dielectric layer.

15. The semiconductor device structure of claim 14, wherein a top surface of the second dielectric layer is curved.

16. The semiconductor device structure of claim 15, wherein the contact etch stop layer interfaces the top surface of the second dielectric layer.

17. A method for forming a semiconductor device structure, comprising:forming a fin structure over a substrate, wherein the fin structure comprises a substrate portion and a first protection layer over the substrate portion;forming an isolation region adjacent the substrate portion, comprising:depositing a first dielectric layer around the fin structure;depositing a second dielectric layer on the first dielectric layer;depositing a third dielectric layer on the second dielectric layer;
recessing the first dielectric layer to expose side surfaces of the first protection layer;
removing the first protection layer;
recessing the first and third dielectric layers; and
recessing the first and second dielectric layers; and
forming a source/drain region over the substrate portion, wherein the source/drain region comprises a first epitaxial layer and a second epitaxial layer, wherein the first epitaxial layer and the second epitaxial layer are doped with a dopant, a concentration of the dopant in the first epitaxial layer is different from a concentration of the dopant in the second epitaxial layer, and a thickness of the source/drain region is different from a width of the source/drain region in a cross-sectional view.

18. The method of claim 17, wherein top surfaces of the first, second, and third dielectric layers are substantially coplanar after the recessing of the first and second dielectric layers.

19. The method of claim 17, wherein top surfaces of the first, second, and third dielectric layers together form a concave surface after the recessing of the first and second dielectric layers.

20. The method of claim 17, wherein the forming of the isolation region further comprises forming a hard mask structure on the first, second, and third dielectric layers, wherein the hard mask structure comprises an oxide layer and a second protection layer.
